(19) United States
(12) Patent Application Publication
(10) Pub. No.: US 2024/0172436 A1
(43) Pub. Date: May 23, 2024

(54) MULTI-LAYERED OXIDE BASED FLASH MEMORY DEVICE USED FOR NEUROMORPHIC COMPUTING SYSTEM

(71) Applicant: KOREA INSTITUTE OF SCIENCE AND TECHNOLOGY, Seoul (KR)

(72) Inventors: Joon Young KWAK, Seoul (KR); Minkyung KIM, Seoul (KR); Suyoun LEE, Seoul (KR); Inho KIM, Seoul (KR); Jong-Keuk PARK, Seoul (KR); Jaewook KIM, Seoul (KR); Jongkil PARK, Seoul (KR); YeonJoo JEONG, Seoul (KR)

(21) Appl. No.: 17/990,333

(22) Filed: Nov. 18, 2022

(51) Int. Cl. H10B 43/27

(52) U.S. Cl. CPC H10B 43/27

(57) ABSTRACT

A flash memory device including multi-layered oxide for neuromorphic computing system is disclosed. According to embodiments, the flash memory device includes: a substrate; a channel layer disposed on the substrate; source/drain patterns disposed on both ends of the channel layer; a tunneling insulating layer disposed on the channel layer; a trapping layer disposed on the tunneling insulating layer and including a plurality of nitride layers; an intermediate barrier layer interposed within the trapping layer, and including an oxide layer, the oxide layer having a high dielectric constant; a blocking insulating layer disposed on the trapping layer; and an upper gate disposed on the blocking insulating layer.

### CROSS-REFERENCE TO RELATED APPLICATIONS

This U.S. non-provisional patent application claims priority under 35 U.S.C. § 119 of Korean Patent Application No. 10-2021-0073569, filed on Jun. 7, 2021, the entire contents of which are hereby incorporated by reference.

### BACKGROUND

The present disclosure herein relates to a flash memory device, and in particular, to a flash memory device using a multi-layer intermediate barrier layer used in a neuromorphic computing system.

Interest in artificial intelligence (AI) has been growing. Fast and accurate calculations are required to process a large amount of data for the recognition of language, images and sounds. However, in the current von Neumann-based computing architecture, a data bus between a CPU and a memory for data information processing is a major obstacle to high-speed and low-power computing for big data.

In this regard, a neuromorphic computing system that mimics the human brain has been attracting attention as a technology that can improve these obstacles in future computing systems. Neuromorphic computing systems can consist primarily of two types of devices: neurons and synapses. Synapses play an important role in transmitting information from presynaptic neurons to postsynaptic neurons. Synapses contain weight information that changes when neuron activity changes the connection strength between neurons.

In neuromorphic computing systems, weights can generally be expressed as conductance levels of synaptic devices. Two-terminal devices such as Memristor (ReRAM, PCRAM, etc.) are being introduced as promising candidates for artificial synapses. As the name implies, a memristor acts as a memory resistor. However, in the process of forming an array for an artificial neural network using a 2-terminal memristor, unwanted leakage current through a sneak path may disturb system implementation. In order to solve this problem, many studies have been conducted, such as using additional selection devices such as transistors, diodes, and OTS (ovonic threshold switch) devices or applying complex pulse inputs.

Recently, as an effort to solve this problem, a three-terminal based synaptic device has been used. The gate of the three-terminal device controls and separates the weight update and read paths, effectively avoiding the sneak path problem. In addition, since the additional selection device required for the two-terminal based synapse array is not required in the three-terminal device, it helps to reduce the overall chip area.

Considering the advantages mentioned above, flash memory devices can be promising candidates for use as synaptic devices in neuromorphic computing systems. Several flash-type synaptic devices, including silicon, carbon nanotube (CNT), and transition metal dichalcogenide (TMDC) based flash memory devices, can improve the problems of existing synaptic devices.

### SUMMARY

The present disclosure provides a flash memory device using a multi-layer intermediate barrier layer for a neuromorphic computing system.

The object of the present disclosure is not limited to the aforesaid, but other objects not described herein will be clearly understood by those skilled in the art from following description.

According to an embodiment of the inventive concept, the flash memory device includes: a substrate; a channel layer disposed on the substrate; source/drain patterns disposed on both ends of the channel layer; a tunneling insulating layer disposed on the channel layer; a trapping layer disposed on the tunneling insulating layer and including a plurality of nitride layers; an intermediate barrier layer interposed within the trapping layer, and including an oxide layer, the oxide layer having a high dielectric constant; a blocking insulating layer disposed on the trapping layer; and an upper gate disposed on the blocking insulating layer.

In embodiments, the nitride layers of the trapping layer and the oxide layer of the intermediate barrier layer are alternately stacked.

In embodiments, the channel layer includes MoS₂, the trapping layer includes Si₃N₄, and the intermediate barrier layer contains Al₂O₃. The linear conductance characteristics and on/off ratio are improved by the intermediate barrier layer.

### BRIEF DESCRIPTION OF THE FIGURES

FIG. 1 is a perspective view illustrating a flash memory device according to an exemplary embodiment of the present invention.

FIGS. 2A and 2B are graphs illustrating electrical characteristics of a flash memory device according to an embodiment of the present invention.

FIG. 3A illustrates a flash memory device according to an exemplary embodiment.

FIG. 3B illustrates a flash memory device according to a comparative example.

FIGS. 4A, 4B, 4C, 4D, and 5 are diagrams illustrating synaptic characteristics of a flash memory device according to the experimental example of the present invention and a flash memory device according to the comparative example.

FIGS. 6A, 6B, and 6C are diagrams showing spike-timing-dependent plasticity (STDP) for changes in synaptic weight over time.

### DETAILED DESCRIPTION

In order to fully understand the configuration and effects of the present invention, preferred embodiments of the present invention will be described with reference to the accompanying drawings. However, the present invention is not limited to the embodiments disclosed below, and may be implemented in various forms and various changes may be applied. In addition, terms used in the embodiments of the present invention may be interpreted as meanings commonly known to those skilled in the art unless otherwise defined. Hereinafter, a flash memory device according to embodiments of the present invention will be described.

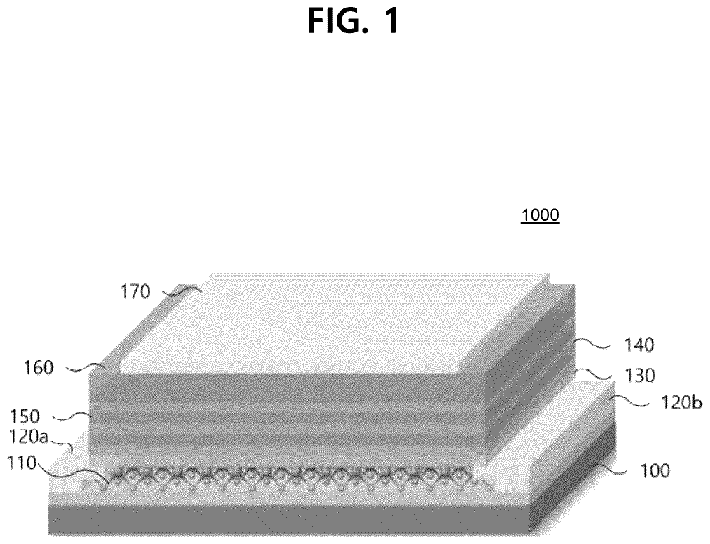

FIG. 1 is a perspective view illustrating a flash memory device according to an exemplary embodiment of the present invention. Referring to FIG. 1, a flash memory device 1000 includes a substrate 100, a channel layer 110, source/drain patterns 120a and 120b, a tunneling insulating film 130, a trapping film 140, and a blocking insulating film 160, and an upper gate 170.

The substrate 100 may be one of an insulating material (e.g., glass), a semiconductor covered with an insulating material, a conductor covered with an insulating material, or a material having semiconductor characteristics (ego, a silicon wafer). According to an embodiment, the substrate 100 may be formed of highly doped p-type Si, and may be obtained by thermally growing SiO2.

The channel layer 110 may be disposed on the substrate 100, and be made of a two-dimensional material. According to one embodiment, the channel layer 110 may include MoS₂. MoS₂ may have a band gap (e.g., 1.2 eV in bulk state and 1.8 eV in the case of monolayer), and may exhibit excellent thermal and ambient stability due to high electrostatic integrity. In addition, the channel layer 110 including MoS₂ may be formed using a metal organic chemical vapor deposition (MOCVD) process.

The source/drain patterns 120a and 120b may be disposed facing each other at both ends of the channel layer 110. Each of the source/drain patterns 120a and 120b may be a Ti/Au electrode sequentially formed by an electron beam deposition process. In this case, the Ti layer may serve as an adhesive layer.

The tunneling insulating layer 130 may be disposed on the channel layer 110 and may cover at least a portion of each of the source/drain patterns 120a and 120b. The tunneling insulating layer 130 may include silicon oxide. For example, the tunneling insulating layer 130 may be formed using a plasma enhanced chemical vapor deposition (PECVD) process.

The trapping layer 140 may include a plurality of nitride layers. According to an embodiment, the nitride layer of the trapping layer 140 may include Si₃N₄ formed by PECVD (Plasma enhanced chemical vapor deposition).

The intermediate barrier layer 150 may include an oxide layer interposed between the plurality of nitride layer of the trapping layer 140. According to an embodiment, the oxide layer of the intermediate barrier layer 150 may include a high-k material having a higher dielectric constant than silicon oxide. For example, the intermediate barrier layer 150 may include Al₂O₃ formed through an atomic layer deposition (ALD) process.

As such, by having a structure in which the intermediate barrier layer 150 is inserted into the trapping layer 140, the number of trap sites may be increased.

The blocking insulating layer 160 may be disposed on the trapping layer 140. The blocking insulating layer 160 may include a high-k material having a higher dielectric constant than silicon oxide. According to an embodiment, the blocking insulating layer 160 may include Al₂O₃ formed by ALD process.

The upper gate 170 may be disposed on the blocking insulating layer 160. The upper gate 170 may include sequentially stacked Ti/Au, and may be formed by an atomic layer deposition process and E-beam deposition.

Electrical Characteristics of Flash Memory Devices

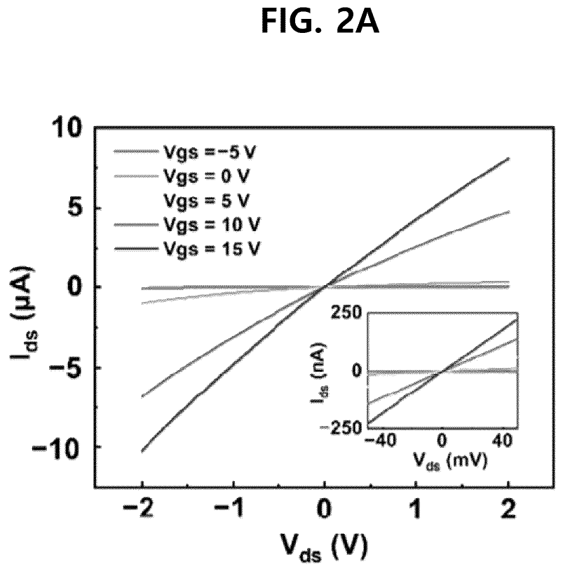

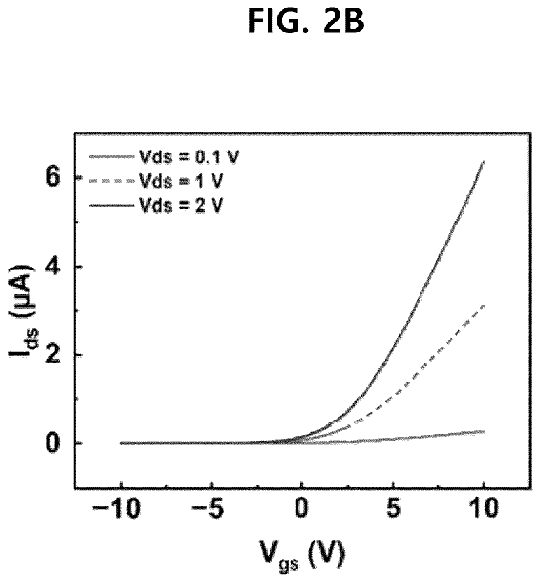

FIGS. 2A and 2B are graphs illustrating electrical characteristics of a flash memory device according to an embodiment of the present invention.

Currents of the drain were measured by sweeping the drain voltage and the gate voltage with the source grounded, respectively, using a two-source measuring device. The linear and symmetric drain-source current (I_{ds}) of the output curve (I_{ds}-V_{ds}) means an ohmic contact between MoS₂ and Ti/Au, as shown in FIG. 2A. FIG. 2B shows the transfer curve (I_{ds}-V_{ds}) measured by sweeping the upper gate in the range of −10V to 10V at various drain-source voltages (V_{ds}) of 0.1V, 1V, and 2V.

According to an embodiment of the present invention, the flash memory device may exhibit n-type operation due to unique characteristics of MoS₂ and have a field-effect mobility of 2.1 cm²V-¹s⁻¹. The field-effect mobility may n be extracted from the transfer curve of FIG. 2B using Equation 1 below.

μ=(dI_{ds}/dV_{gs})·(L/WV_{ds}Cᵢ) [Equation 1]

where L is a length (5 μm), W is a channel width of the flash memory device (5 μm), and Ci is a capacitance of the gate insulator per unit.

A voltage pulse (V_{gs}) representing a neuronal spike train may be continuously applied to the upper gate to mimic the potentiation behavior and depression behavior of a biological synapse. The working mechanism of flash memory devices may be related to tunneling hot electrons and charge trapping states. When a negative voltage pulse is applied to the upper gate electrode, some of the electrons trapped in the three nitride layers are released into the channel layer. As a result, the flash memory device may move to a low threshold voltage state (erase state), and the channel current (conductance) may increase. On the other hand, when a positive voltage pulse is applied to the upper gate electrode, the three nitride layers may be gradually charged by electrons tunneled from the channel layer, and may have a high threshold state (program state). This state of the three nitride layers effectively reduces the channel current (conductance).

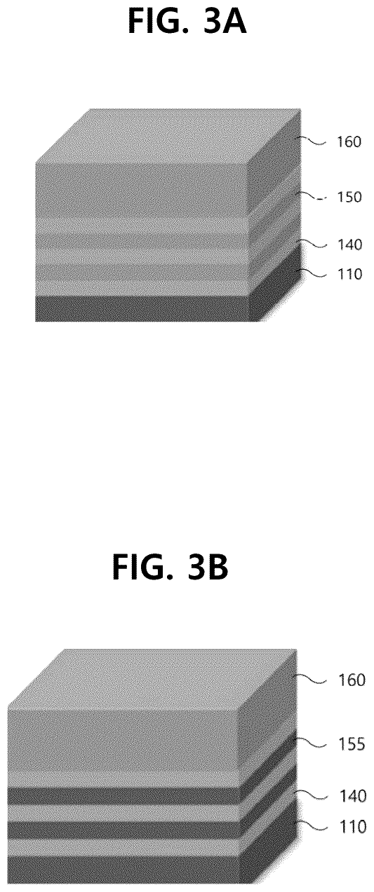

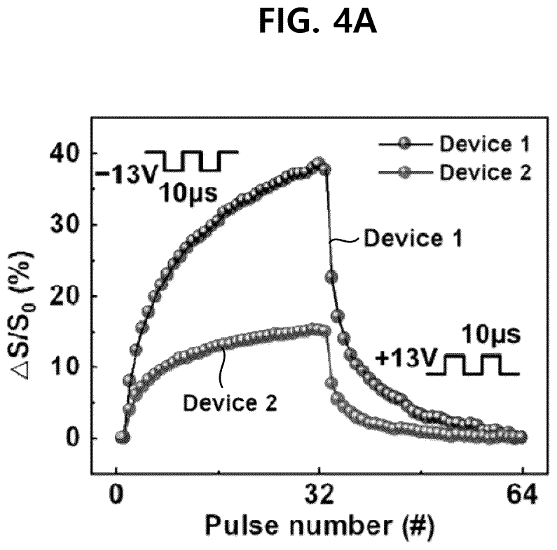

Hereinafter, synaptic characteristics of a flash memory device according to an experimental example of the present invention and a flash memory device according to a comparative example will be described. FIG. 3A illustrates a flash memory device according to an experimental example. FIG. 3B illustrates a flash memory device according to a comparative example.

### Embodiment Example

Referring to FIG. 3A, SiO₂ layer with 4 nm thickness is used as the tunneling oxide layer 110 on the substrate, and Al₂O₃ layer with 6 nm thickness is used for the blocking oxide layer 160. Between the tunneling oxide layer 110 and the blocking oxide layer 160, Si₃N₄ layer with 2 nm thickness and Al₂O₃ layer with 2 nm thickness are alternately stacked five times to form nitride layers of the trapping layers 140 and oxide layers of an intermediate barrier layer 150.

### Comparative Example

Referring to FIG. 3B, SiO₂ layer with 4 nm thickness is used as the tunneling oxide layer 110 on the substrate, and Al₂O₃ layer with 6 nm thickness is used for the blocking oxide layer 160. Between the tunneling oxide layer 110 and the blocking oxide layer 160, Si₃N₄ layer with 2 nm thickness and SiO₂ layer with 2 nm thickness are alternately stacked five times to form nitride layers of a trapping layer 140 and oxide layers 155 of an intermediate barrier layer. That is, comparative example is the same as the experimental example except that the SiO₂ layers are used as the oxide layers of the intermediate barrier layer.

### Experimental Example

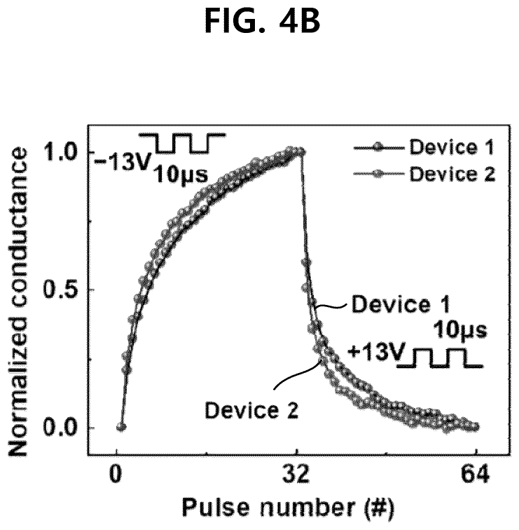

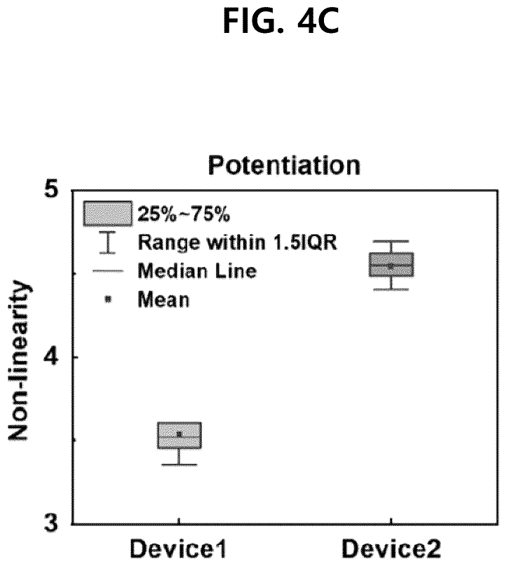

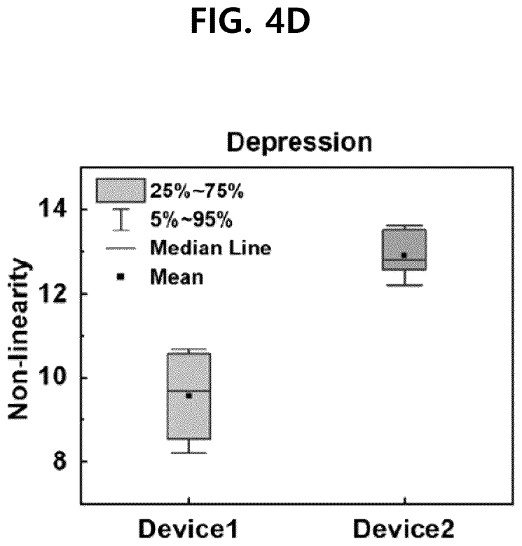

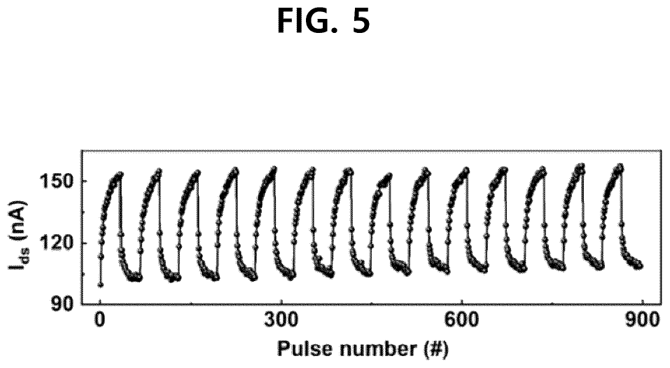

FIGS. 4A to 4D and FIG. 5 are diagrams illustrating synaptic characteristics of a flash memory device according to the experimental example of the present invention and a flash memory device according to the comparative example.

FIGS. 4A and 4B show the potentiation and inhibition curves of synaptic apparatus having 32 states of synaptic weight. Continuous voltage pulses of −13 V with a pulse width of 10 μs for potentiation, and continuous voltage pulses of +13 V with a pulse width of 10 μs for suppression are continuously applied to the upper gate to update the weights, and after each of pulses is applied, reading the channel current (or conductance) was conducted. The experimental example shows a higher conduction on/off ratio than the comparative example by having Al₂O₃ layers as oxide layers of the intermediate barrier layer. This is due to contributions of the coupling ratio between comparative example and experimental example. The coupling ratio of the flash memory device is determined as a portion of a voltage applied across a tunneling oxide layer(tunneling insulating layer) under a predetermined voltage at the upper gate. Therefore, a greater coupling ratio results in a higher tunneling voltage applied between the channel layer and the trapping layer.

The coupling ratios measured in the experimental example and the comparative example were 0.34 and 0.28, respectively. From these measurements, as shown in FIGS. 4A and 4B, the experimental example with a high coupling ratio shows a larger conductance on/off ratio and better linearity potentiation and suppression curves.

A high coupling ratio may enhance the tunneling efficiency and the memory window for threshold voltage shift, thus improving the synaptic operation of the flash memory device. FIGS. 4c and 4d show nonlinear values obtained by performing 14 cycles of potentiation and suppression behaviors of the experimental example and the comparative example. The nonlinearity factor may be derived from Equations 2 and 3 below.

Potentiation:

Gₚₒₜ=G₁(1−e^{-νP})+Gₘᵢₙ [Equation 2]

Depression:

G_{dep}=Gₘₐₓ−G₁(1−e^{-ν(1-P)}) [Equation 3]

At this time, in

$${G}_{1} = \frac{{G}_{max} - {G}_{min}}{1 - {e}^{- v}} ,$$

Gₘₐₓ and Gₘᵢₙ are the maximum and minimum conductance, respectively, and v is a parameter of nonlinearity. P is the normalized number of pulses.

In the potentiation behavior, the average nonlinearity values in the 32 conductance steps in the experimental example and the comparative example are estimated to be 3.49 and 4.48, respectively. In the suppression behavior, the average nonlinearity values of the experimental example and the comparative example are estimated to be 8.27 and 12.76, respectively. FIG. 5 shows the robustness of the synaptic apparatus through the repetitive process of 896 voltage pulses in the depression and repression behaviors.

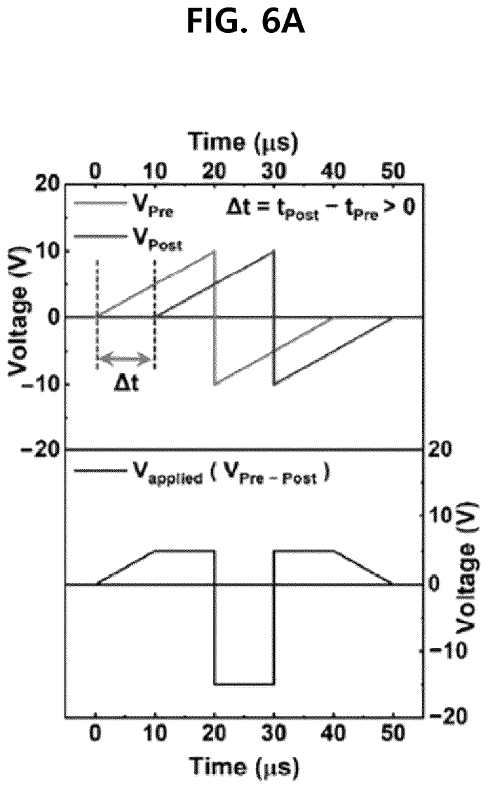

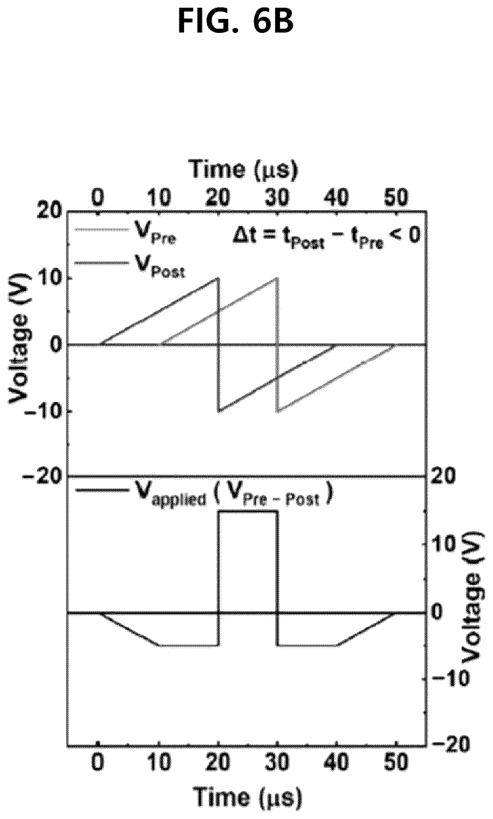

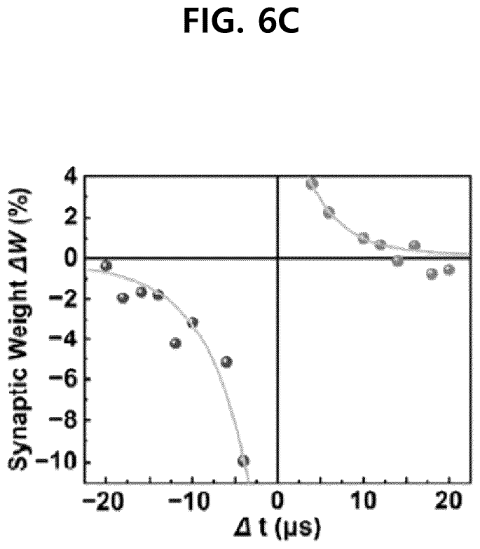

Hereinafter, FIGS. 6A to 6C are diagrams showing spike-timing-dependent plasticity (STDP) for synaptic weight changes over time.

Synaptic weight updates based on STDP learning rules are demonstrated to mimic biological processes in SNN-based neuromorphic systems. STDP behavior modulates synaptic weight information between pre-synaptic and post-synaptic neurons according to the relative spike timing difference. To show the STDP behavior, in FIGS. 6A and 6B, a pulse set (V_{applied}) of a different shape including timing difference information (Delta time=tₚₒₛₜ−tₚᵣₑ) between a pre-synaptic pulse (Vₚᵣₑ) and a post-synaptic pulse (Vₚₒₛₜ) is applied to the upper gate.

If Vₚᵣₑ spikes before Vₚₒₛₜ (positive delta time case), the synaptic weight increases, whereas if Vₚₒₛₜ spikes before Vₚᵣₑ (negative delta time case), the synapse is weakened. FIG. 6c shows amounts of changes of the synaptic weight (conductivity) at each delta time. The exponential fit line of both polarities represents a well-operated STDP learning rule. That is, the shorter the delta time, the larger the weight change.

The oxide layers of the intermediate barrier layer containing a high-k oxide may increase the memory threshold voltage shift window of the flash memory device, resulting in a higher on/off ratio and excellent linear conductance change. In addition, it suggests that the flash memory device according to an embodiment of the present invention may be one of the viable synaptic devices for the SNN-based neuromorphic system.

According to the embodiments, a flash memory device may improve a high on/off ratio and linear conductance by using an intermediate barrier layer stack having a high dielectric constant material. In addition, a spiking neural network (SNN)-based neuromorphic computing system may be implemented by emulating spike-timing-dependent plasticity (STDP) in the flash memory device of the present invention.

Although the embodiments of the present invention have been described with reference to the accompanying drawings, those skilled in the art can understand that the present invention in other specific forms can be implemented without changing the technical spirit or essential features. Therefore, it should be understood that the embodiments described above are illustrative in all respects and not limiting.

1. A flash memory device comprising:
a substrate;
a channel layer disposed on the substrate;
source/drain patterns disposed on both ends of the channel layer;
a tunneling insulating layer disposed on the channel layer;
a trapping layer disposed on the tunneling insulating layer and including a plurality of nitride layers;
an intermediate barrier layer interposed within the trapping layer, and including an oxide layer, the oxide layer having a high dielectric constant;
a blocking insulating layer disposed on the trapping layer; and
an upper gate disposed on the blocking insulating layer.

2. The flash memory device of claim 1, wherein the nitride layers of the trapping layer and the oxide layer of the intermediate barrier layer are alternately stacked.

3. The flash memory device of claim 1, wherein the channel layer includes MoS₂,
the trapping layer includes Si₃N₄, and
the intermediate barrier layer contains Al₂O₃.

4. The flash memory device of claim 1, wherein the linear conductance characteristics and on/off ratio are improved by the intermediate barrier layer.
